(19) United States
(12) Patent Application Publication
(10) Pub. No.: US 2025/0151228 A1
(43) Pub. Date: May 8, 2025

(54) HYBRID LIQUID COOLING SYSTEM FOR ELECTRONICS

(71) Applicant: Apollo Autonomous Driving USA LLC, Sunnyvale, CA (US)

(72) Inventor: Peng Cheng, Sunnyvale, CA (US)

(21) Appl. No.: 18/503,702

(22) Filed: Nov. 7, 2023

(51) Int. Cl. H05K 7/20

(52) U.S. Cl. CPC H05K 7/20236; H05K 7/20254; H05K 7/20263; H05K 7/20272

(57) ABSTRACT

Embodiments are disclosed of a hybrid liquid cooling apparatus. The apparatus includes a housing having a lid, a bottom, and at least one sidewall. The lid, the bottom, and the at least one sidewall form a sealed enclosure adapted to be at least partially filled with an immersion cooling fluid. A printed circuit board assembly (PCBA) positioned in the sealed enclosure. The PCBA includes one or more major electronic components and one or more minor electronic components. At least part of a cold plate is positioned in the sealed enclosure, is thermally coupled to the one or more major components, and is at least partially submerged in the immersion cooling fluid.

### TECHNICAL FIELD

The disclosed embodiments relate generally to hybrid liquid cooling systems for electronics, and more specifically, but not exclusively, to a hybrid liquid cooling apparatus and system for electronics used in non-ideal environmental conditions such as in vehicles.

### BACKGROUND

Mobile computing devices, whether hand-held, in a vehicle, or otherwise mobile, have become ubiquitous. Modern vehicles in particular have many onboard computers-so many that a vehicle is now much like a mobile data center. Real data centers use extensive environmental control systems, such as air conditioning, to keep computing equipment in a tightly controlled environment—that is, data centers keep ambient conditions such as temperature and humidity within tightly controlled limits. But vehicles are stored and operated in much more variable ambient conditions: the interior compartments of a vehicle parked or driven outdoors on a hot day can become very hot and humid, and on a cold winter day they can become very cold and dry.

Vehicles usually have environmental control systems, but they exist mostly for passenger comfort and operate only when the vehicle itself is operating, making it difficult or impossible to keep a vehicle's onboard computers within tight environmental limits when the vehicle is exposed to ambient conditions. And even during vehicle operation, some compartments like the engine compartment are not cooled by the vehicle's environmental control system and can become quite hot. As a result, onboard computers positioned in vehicle compartments are also subjected to a wide range of temperatures, humidities, etc.

Repeatedly exposing electronics to high and low temperatures, especially when coupled with high humidity, can cause dysfunction, lifetime shortening, or permanent damage. For safety-critical computing hardware in autonomous driving systems—for instance, computers for level four (L4) and level five (L5) fully autonomous driving (i.e., driverless) platforms, which have complicated circuit architectures and include a variety of functional components-reliability over a wide range of temperature and humidity is a critical consideration to ensure consistent performance, safety, and cost-efficiency.

### BRIEF DESCRIPTION OF THE DRAWINGS

Non-limiting and non-exhaustive embodiments of the invention are described below with reference to the following figures, wherein like reference numerals refer to like parts throughout the various views unless otherwise specified.

FIGS. 1A-1C are views of an embodiment of a hybrid liquid cooling device and system. FIG. 1A is an exploded side view of the device, FIG. 1B an assembled side view of the device, and FIG. 1C a plan view of the system.

FIG. 2 is a side view of an embodiment of a printed circuit board (PCB) connection that can be used with the hybrid liquid cooling device of FIGS. 1A-1C and FIGS. 4A-4B.

FIG. 3 is a side view of another embodiment of a PCB connection that can be used with the hybrid liquid cooling systems of FIGS. 1A-1C and FIGS. 4A-4B.

FIGS. 4A-4B are side views of another embodiment of a hybrid liquid cooling device. FIG. 4A is an exploded view, FIG. 4B an assembled view.

FIG. 5 is a plan view of an embodiment of a vehicle using an embodiment of a hybrid liquid cooling device such as the ones shown in FIGS. 1A-1C, 2, 3, and 4A-4B.

### DETAILED DESCRIPTION

Embodiments are described of a hybrid liquid cooling apparatus and system for cooling electronics. Specific details are described to provide an understanding of the embodiments, but one skilled in the relevant art will recognize that the invention can be practiced without one or more of the described details or with other methods, components, materials, etc. In some instances, well-known structures, materials, or operations are not shown or described in detail but are nonetheless within the scope of the invention.

Reference throughout this specification to “one embodiment” or “an embodiment” means that a described feature, structure, or characteristic can be included in at least one described embodiment, so that appearances of “in one embodiment” or “in an embodiment” do not necessarily all refer to the same embodiment. Furthermore, the described features, structures, or characteristics can be combined in any suitable manner in one or more embodiments. As used in this application, directional terms such as “left,” “right,” “front,” “rear,” “upper,” lower,” “top,” “bottom,” “side,” “lateral,” “longitudinal,” etc., refer to the orientations of embodiments as they are presented in the drawings, but any directional term should not be interpreted to imply or require a particular orientation of the described embodiments when in actual use.

Embodiments are described below of a hybrid liquid cooling apparatus and system for cooling electronics, especially those in vehicles that are subject to widely-varying environmental conditions. Vehicle computing systems, especially those for autonomous driving, usually include multiple powerful processing units that are used for vehicle control, positioning, navigation, communication, and running algorithms for manipulating perception data, etc. These processors need a well-designed cooling system to control the components' temperature within the specified limits. At the same time, cooling systems should consider implementing, as comprehensively as possible, designs for low profile, compact form factor, vibration resistance, and humidity/dust protection. Beyond these major power-consuming processors, many other integrated circuits (ICs) integrated into the PCB require cooling, such as MOSFET, storage chips, and voltage regulators. The described embodiments are of hybrid liquid cooling systems for handling major and minor heat-generating components.

Liquid cooling can sufficiently address the cooling demand of high-performance computing systems and other supplementary requests for compactness, mobility, and resistance to severe environments. But existing liquid cooling technologies have some limitations and difficulties, especially when deployed to automobile systems. For direct liquid cooling, its liquid loop is easy to integrate into the thermal management systems of vehicle components such as the engine, cabinet, or battery packs. But the cold plate must usually cover all of the heat-generating components of the electronics, even for the components having only minor heat dissipation. This makes the cold plate geometrically complicated. Multiple boards are sometimes stacked and interconnected by inner connectors, and components underneath cannot thermally contact the cold plate. Single-phase or two-phase immersion cooling can readily deal with cooling components that are blocked from the cold plate, but a disadvantage is that immersion cooling must use a separate liquid loop and therefore needs dedicated pumping and heat exchange systems. And sealing the immersion cooling fluid can be a problem for automotive applications due to the need for external connectors.

The embodiments below are hybrid cooling devices and systems that combine direct liquid cooling with immersion cooling. Direct liquid cooling uses cold plates mounted onto heat-generating components and circulates a liquid circulation coolant through the cold plate for cooling. Immersion cooling submerges electronics in a dielectric fluid, such as mineral oils, and cools the electronics using one of two ways: single-phase immersion cooling, which submerges, and cools the components via the natural convection or forced convection of the fluid, or two-phase immersion cooling, which also uses dielectric fluid but is more volatile that the evaporation and condensation of the fluid carry over the cooling. The embodiments enable high performance and efficiency thermal management of increasingly powerful electronic components operating in non-ideal environments.

In one aspect, the hybrid liquid cooling device includes a housing having a lid, a bottom, and at least one sidewall. The lid, the bottom, and the at least one sidewall form a sealed enclosure adapted to be at least partially filled with an immersion cooling fluid. A printed circuit board assembly (PCBA) is positioned in the sealed enclosure; the PCBA can include one or more major electronic components and one or more minor electronic components. A cold plate at least part of which is positioned in the sealed enclosure, wherein the cold plate is thermally coupled to the one or more major components and is at least partially submerged in the immersion cooling fluid.

In an embodiment, the cooling device further includes baffles positioned in the sealed enclosure to prevent sloshing of the immersion cooling fluid. In another embodiment the cooling device further includes a board-end connector coupled to the PCBA. In yet another embodiment of the cooling device the board-end connector extends through the at least one sidewall from an interior side of the sidewall to an exterior side of the sidewall, another embodiment further includes a seal positioned at or near where the board-end connector exits the exterior side of the sidewall, and yet another embodiment further includes a cable-end connector connected to the board-end connector and extending through the lid. Still another embodiment further includes a fill port for filling the sealed enclosure with the immersion cooling fluid and a drain port for draining the immersion cooling fluid from the sealed enclosure. Another embodiment further includes a forced-convection device positioned in the sealed enclosure to force convection of the immersion cooling fluid. And in yet another embodiment the lid is formed by the cold plate.

In another aspect, an electronics cooling system includes a housing having a lid, a bottom, and at least one sidewall. The lid, the bottom, and the at least one sidewall form a sealed enclosure adapted to be at least partially filled with an immersion cooling fluid. A printed circuit board assembly (PCBA) is positioned in the sealed enclosure. The PCBA including one or more major electronic components and one or more minor electronic components. A cold plate, at least part of which is positioned in the sealed enclosure, is thermally coupled to the one or more major components and is at least partially submerged in the immersion cooling fluid. A heat exchanger is fluidly coupled to an inlet and an outlet of the cold plate, wherein the heat exchanger is positioned outside the sealed enclosure, and a pump is coupled between the cold plate and the heat exchanger to circulate a circulation cooling fluid through the cold plate and the heat exchanger.

In an embodiment, the pump is coupled upstream of the inlet of the cold plate. Another embodiment further includes a board-end connector coupled to the PCBA, and in yet another embodiment the board-end connector extends through the at least one sidewall from an interior side of the sidewall to an exterior side of the sidewall. Still another embodiment further includes seals positioned at or near where the board-end connector exits the exterior side, and another embodiment further includes a cable-end connector connected to the board-end connector and extending through the lid. In yet another embodiment, the lid is formed by the cold plate.

In another aspect, an electronics cooling system for a vehicle includes a cooling apparatus positioned in a compartment of the vehicle. The cooling apparatus includes a housing having a lid, a bottom, and at least one sidewall, and the lid, the bottom, and the at least one sidewall form a sealed enclosure adapted to be at least partially filled with an immersion cooling fluid. A printed circuit board assembly (PCBA) is positioned in the sealed enclosure, and the PCBA includes one or more major electronic components and one or more minor electronic components. A cold plate, at least part of which is positioned in the sealed enclosure, is thermally coupled to the one or more major components and is at least partially submerged in the immersion cooling fluid. A heat exchanger is positioned outside the sealed enclosure and fluidly coupled to an inlet and an outlet of the cold plate, and a pump is coupled between the cold plate and the heat exchanger to circulate a circulation cooling fluid through the cold plate and the heat exchanger.

In one embodiment, the cooling system further includes a board-end connector coupled to the PCBA and, in another embodiment, the board-end connector extends through the at least one sidewall from an interior side of the sidewall to an exterior side of the sidewall, and further includes seals positioned at or near where the board-end connector exits the exterior side. And another embodiment further includes a cable-end connector connected to the board-end connector and extending through the lid.

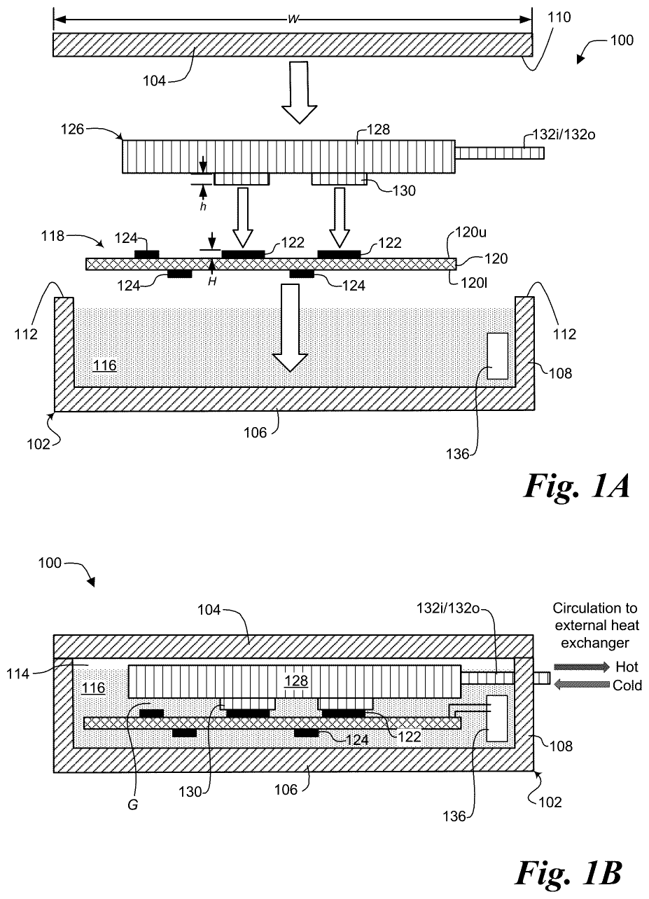

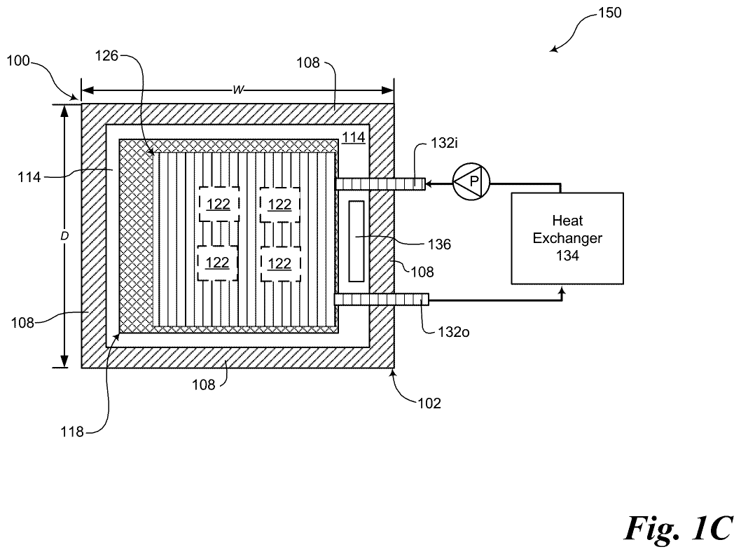

FIGS. 1A-1C together illustrate an embodiment of a hybrid liquid cooling device 100. FIG. 1A is an exploded view of the device, FIG. 1B an assembled view of the device, and FIG. 1C a plan view of a system using the device. Device 100 includes a housing with a body 102 and a lid 104. Body 102 includes a bottom 106 and at least one sidewall 108. In the illustrated embodiment, body 102 has a quadrilateral plan-view shape (see FIG. 1C) with four sidewalls 108, but in other embodiments the plan-view shape need not be quadrilateral but can be any polygonal shape, so that body 102 can have more or less sidewalls than shown. In still other embodiments the plan-view shape of body 102 need not be a polygon, but can be a curved shape such as a circle or ellipse, in which case body 102 can be thought of as having a single sidewall 108.

Lid 104 has a bottom surface 110 that can engage with the top ends 112 of sidewalls 108. When the body and lid are assembled, surface 110 engages with the top ends 112 so that the body and lid define, or form the boundaries of, a sealed enclosure 114 (see FIG. 1B). In one embodiment the plan-view shape and size of lid 104 substantially match the shape and size of body 102, but in other embodiments the shape and size of the lid need not match the shape and size of the body. Sealed enclosure 114 is adapted to be at least partially filled with an immersion cooling fluid 116 that cools components that are immersed in it. In one embodiment immersion cooling fluid 116 is a dielectric fluid with a high thermal conductivity or a high specific heat capacity—that is, a fluid that does not conduct electricity but conducts or absorbs heat well—but in other embodiments it can be a different type of fluid. Generally, dielectric fluids are denser and more viscous than non-dielectric fluids. Although not shown in the figure, one or more seals such as gaskets, O-rings, or the like can be positioned between top ends 112 and bottom surface 110 to create a seal that prevents immersion cooling fluid 116 from leaking out of sealed enclosure 114.

A printed circuit board assembly (PCBA) 118 is positioned within sealed enclosure 114 so that it will be fully immersed in immersion cooling fluid 116 when the immersion cooling fluid is present. PCBA 118 includes a substrate 120 having an upper surface 120U and a lower surface 120L. In one embodiment, substrate 120 is a printed circuit board (PCB) including conductive traces on its surface, in its interior, or both, but in other embodiments it can be a different type of substrate. In the illustrated embodiment of PCBA 118, electronic components are mounted on both upper surface 120U and lower surface 120L of PCB 120, but in other embodiments electronic components can be mounted on only the upper surface or the lower surface.

Electronic components are mounted on substrate 120. In the illustrated embodiment, the electronic components mounted on upper surface 102U include major electronic components 122 and a minor electronic component 124 and the electronic components on lower surface 102L include only minor components 124. In the illustrated embodiment there are two major components 122 and one minor component on upper surface 102U, and there are two minor components 124 on lower surface 120L. But other embodiments can have different numbers of major and minor components than shown on the upper and lower surfaces. A major component is one whose power consumption equals or exceeds a certain threshold, while a minor component is one whose power consumption is below the threshold. Generally, the higher a component's power consumption the more heat it generates and dissipates, so that major components generate and dissipate more heat than minor components. In one embodiment the power consumption threshold can be approximately 10 W, but other embodiments can use thresholds higher or lower than 10 W. For instance, in one embodiment the threshold can be between approximately 5 W and approximately 800 W.

Although designated with the same reference numerals, all major components 122 need not be the same type of component, and similarly all minor components need not be the same type of component. Examples of major components that can be cooled with the cold plate include elements such as a CPU, GPU, FPGA, TPU, MCU, DIMMs, etc. Examples of minor components that can be cooled by immersion cooling include Mosfets, voltage regulators, resistors, conductors, inductors, etc.

Cold plate 126 is placed in sealed enclosure 114 above PCBA 118 and is positioned so that it is thermally coupled to major components 122. Cold plate 126 includes a main body 128 and protrusions 130. The main body includes an internal chamber (not shown) through which a cooling fluid circulates; this cooling fluid is referred to herein as the circulating cooling fluid. In one embodiment the circulating fluid and the immersion cooling fluid are different fluids. Cold plate can implement forced convection of single-phase coolant or convective evaporation of two-phase coolant for cooling.

Main body 128 is fluidly coupled to a heat exchanger and pump that are outside sealed enclosure 114 (see, e.g., FIG. 1C) by a fluid interface that includes an inlet 132i and an outlet 1320. In the illustrated embodiment, inlet 132i and outlet 1320 extend through a sidewall 108 of main body 102, but in other embodiments the inlet and outlet can be positioned differently than shown. Also in the illustrated embodiment the inlet and outlet extend through the same sidewall 108, but in other embodiments they need not extend through the same sidewall. In an embodiment that could be considered to have a single sidewall, such as one with a circular or elliptical main body 102, the inlet and outlet need not be adjacent to or near each other.

In embodiments in which major components 122 have different heights H, cold plate 126 can include protrusions 130 whose height h can be tailored to the different heights H of the major components. The protrusions ensure that when cold plate 126 is installed it will be in thermal contact with all major components 122, regardless of their height H. When present, protrusions 130 are thermally and fluidly coupled to the internal chamber within main body 128, so that heat can be transferred through the protrusions into the circulating fluid. Protrusions 130 can also be used to create a gap G—i.e., a non-zero distance—between main body 128 and minor components 124 positioned on upper surface 120u. Gap G allows immersion cooling fluid 116 to circulate around minor components 124 on upper surface 120U, thus improving heat transfer from these components. The gap also prevents electrical shorts that could occur if main body 128 comes into physical contact with a minor component 124. Main body 128 and protrusions 130 are made of materials that are highly thermal thermally conductive to ensure heat transfer efficient heat transfer from major components 122 into the circulating cooling fluid. In one embodiment, main body 128 and protrusions 130 can be made of metal, but other embodiments they can be made of thermally conductive non-metals. In still other embodiments, main body 128 and protrusions 130 need not all be made of the same material.

A forced-convection device 136 can be positioned within sealed enclosure 114 so that it will be at least partially submerged in immersion cooling fluid 116 when the immersion cooling fluid is put in the sealed enclosure. As heat is transferred from major devices 122 and minor devices 124 into the immersion cooling fluid, and as the entire device 100 moves, there will be some amount of natural convection in the immersion cooling fluid. But in some embodiments, it might be desirable to force additional convection of the immersion cooling fluid to increase the total convection and improve heat transfer. Forced-convection device 136 can be used to create this forced convection.

The forced-convection device is electrically connected to PCB 120 so that it gets its electrical power from the PCB. The illustrated embodiment has a single forced-convection device 136, but other embodiments can include multiple forced-convection devices. In one embodiment the forced convection device can be fan, but in other embodiments it can be a pump or some other convection-forcing device such as a micro-blower. In the illustrated embodiment, forced-convection device 136 is positioned at an edge of sealed enclosure 114 near a sidewall 108, but in other embodiments the forced-convection device can be positioned differently within sealed enclosure 114. Still other embodiments can omit forced-convection device 136 if natural convection of the immersion cooling fluid provides adequate cooling.

FIG. 1C illustrates an embodiment cooling system 150 using device 100 coupled to an external heat exchanger. Cooling device 100 is as described above for FIGS. 1A-1B, with body 102 and lid 104 forming sealed enclosure 114, and PCBA 118, cold plate 126, and optionally forced-convection device 136 positioned in the sealed enclosure. A similar cooling system can be implemented with devices 200, 300, or 400.

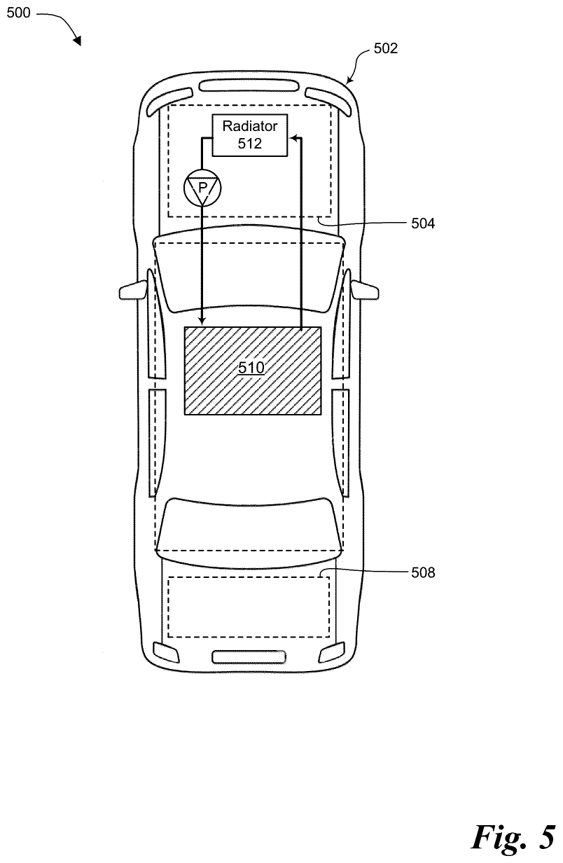

Cold plate 126 is fluidly coupled to heat exchanger 134 to form a cooling loop. The inlet of cold plate 126 is coupled to the outlet of heat exchanger 134, and the outlet of the cold plate is fluidly coupled to the inlet of the heat exchanger. A pump P is positioned in the fluid line between heat exchanger 134 and the inlet of cold plate 126 to help circulate the circulation cooling fluid through both cold plate 126 and heat exchanger 204. In an automotive embodiment, heat exchanger 134 can be a vehicle's primary heat exchanger—a radiator, for instance (see FIG. 5)—but in other automotive embodiments heat exchanger 134 can be a heat exchanger separate from the vehicle's radiator. Also in an automotive embodiment, pump P can be the vehicle's own cooling pump, but in other embodiments pump P can be a separate pump, for instance a pump specifically dedicated to circulating cooling liquid through cold plate 126. For automotive applications such as autonomous driving vehicles, the circulated coolant may share the thermal management system with other vehicle parts, e.g., the battery pack, so the heat transfer scheme in the cold plate may be restrained from two-phase evaporative cooling.

In operation of device 100, immersion cooling fluid 116 and cold plate 126 work together simultaneously to cool the major and minor electrical components. Immersion cooling fluid 116 primarily cools the minor components, although it can also absorb some heat from the major components that are immersed in it. Cold plate 126 primarily cools the major component but, because the cold plate is also at least partially submerged in the immersion cooling fluid, also helps cool the immersion cooling fluid. Thus, in addition to cooling the major components, the cold plate indirectly cools the minor components by helping cool the immersion cooling fluid.

When in use, minor components 124 transfer heat into immersion cooling fluid 116. Immersion cooling fluid 116 can absorb enough heat to cool components having no contact with the cold plate, and the immersion cooling fluid dissipates heat to the body 102, lid 104, and further to the cold plate 126. For automotive applications, acceleration and deceleration of the vehicle will cause the flow of the immersion cooling fluid and provide additional convection force. The immersion cooling fluid also prevents dust and humidity from contaminating the computing system. Simultaneously, pump P pumps cool circulating cooling fluid from heat exchanger 134 through inlet 132i into the cold plate's main body 128. The circulating cooling fluid flows through the cold plate's internal chamber and absorbs heat from major components 122 to which the cold plate is thermally coupled, as well as absorbing some heat from immersion cooling fluid 116. Having absorbed heat through the cold plate, the circulating fluid becomes hot, and this now-hot circulating fluid then flows from the cold plate back to the heat exchanger through outlet 1300. Heat exchanger 132 dissipates heat from the hot circulating fluid, thus cooling it, and the cycle is then repeated by pumping the now-cold circulating fluid back into the cold plate.

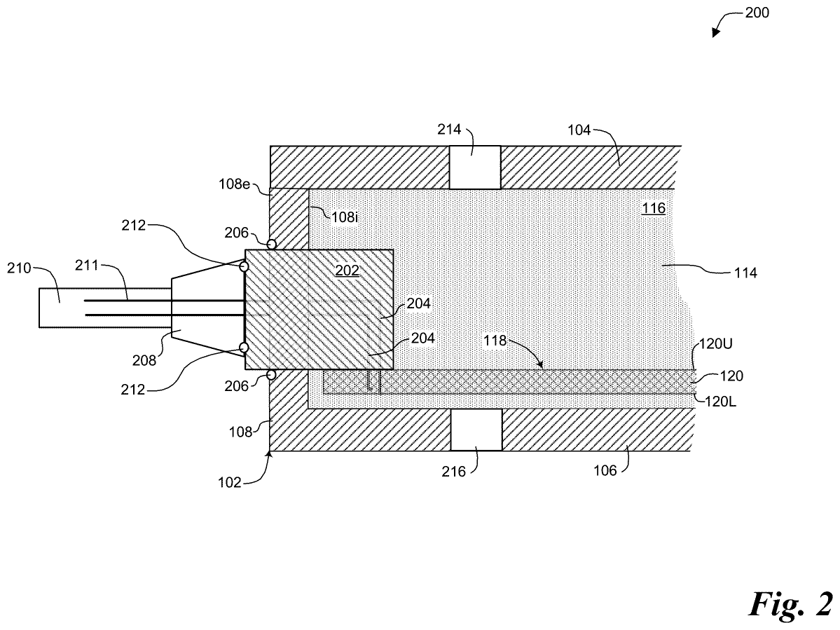

FIG. 2 illustrates an embodiment of a hybrid liquid cooling device 200 with an external connector. Cooling device 200 is substantially similar to cooling device 100: it includes substantially the same primary components, assembled in the same way and subject to the same variations in different embodiments. Cooling device 200 thus includes a body 102 and a lid 104, with the bottom surface of lid 104 sealingly attached to the ends of sidewalls 108 so that the body and lid form a sealed enclosure 114 that can be at least partially filled with immersion cooling fluid 116. PCBA 118 includes PCB 120 and all the major and minor electronic components attached to its upper surface 120U and lower surface 120L; the electronic components not shown in this figure, but see FIGS. 1A-1C. PCBA 118 is positioned within sealed enclosure 114 so that it will be at least partially submerged in immersion cooling fluid 116, and cold plate 126 (also not shown in this figure, but see FIGS. 1A-1C) is thermally coupled to the major components on top surface 120U.

One concern for the immersion cooling part of the system is the sealing around external connectors. In some circumstances it can be necessary to connect and disconnect PCBA 118, and its components, from various external connections (e.g., power, network, and data connections to components outside sealed compartment 114) without leaking or spilling immersion cooling fluid 116. The illustrated connector arrangement provides this capability by using a waterproof design between the connector casing and sidewall and between the mating faces of the board-end and cable-end connectors.

In the illustrated embodiment, a board-end connector 202 is mounted on PCB 120. In the illustrated embodiment, the board-end connector is mounted on upper surface 120U, but in other embodiments it could also be positioned on lower surface 120L. Board-end connector 202 is electrically coupled to PCB 120, and thus to the components mounted on the PCB, through conductive paths 204 that extend through the board-end connector. In one embodiment conductive paths 204 can be wires embedded in the board-end connector, but in other embodiments they can be other types of conductive paths or traces within the board-end connector.

Board-end connector 202 also extends completely through sidewall 108—that is, the board-end connector extends from inside sealed enclosure 114, in through internal surface 108i of the sidewall, and out through external surface 108e of the sidewall. To prevent leakage of immersion cooling fluid 116, board-end connector 202 is sealed where it exits through external surface 108e. In the illustrated embodiment the seal between board-end connector 202 and external surface 108e is formed by an O-ring 206, but in other embodiments the seal can be formed differently than shown. In the illustrated embodiment there is no seal where board-end connector 202 intersects internal surface 108i, but in other embodiments a seal can be formed at this location instead of, or in addition to, the seal where board-end connector 202 extends through external surface 108e.

A cable-end connector 208 and its associated cable 210 can include wires 211 that make electrical contact with conductive paths 204 when cable-end connector 208 is mated with board-end connector 202. Cable-end connector 208 mates with board-end connector 202. To prevent potential leaks at the interface of the cable-end and board-end connectors, a seal 212 can be placed where cable-end connector 208 mates with board-end connector 202 at the interface where they meet. In the illustrated embodiment, the seal 212 is an O-ring, but in other embodiments the seals can be implemented differently. In one embodiment, board-end connector 202 and cable-end connector 208 can be a water-proof connectors that can reach the IP67 standard for ingression protection.

To allow for removal of elements such as PCBA 118 and board-end connector 202 from sealed enclosure 114, cooling device 200 includes a fill port 214 in lid 104 and a drain port 216 in bottom 106. In one embodiment, the sealed enclosure can be filled with immersion cooling fluid after installation and plugging of the cables, and the immersion cooling fluid can be drained before unplugging the cables. During draining, fill port 214 can work as a venting hole to balance the pressure in the sealed enclosure.

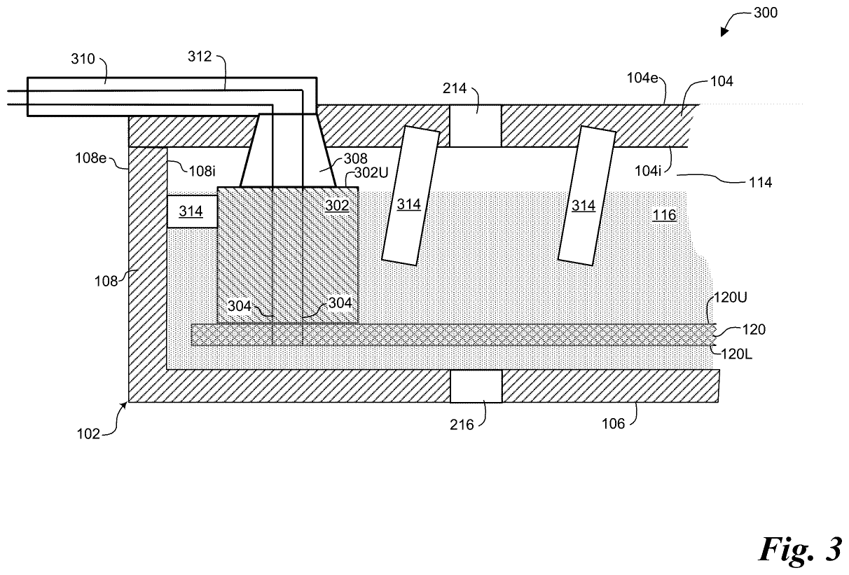

FIG. 3 illustrates another embodiment of a hybrid liquid cooling device 300 with an external connector. Cooling device 300 is substantially similar to cooling device 200: it includes substantially the same primary components, assembled in the same way and subject to the same variations in different embodiments. Cooling device 300 thus includes a body 102 and a lid 104, with the bottom surface of lid 104 sealingly attached to the tops of sidewalls 108 so that the body and lid form a sealed enclosure 114 that can be at least partially filled with immersion cooling fluid 116. PCBA 118 includes PCB 120 and all the major and minor electronic components attached to its upper surface 120U and lower surface 120L; the electronic components not shown in this figure, but see FIGS. 1A-1C. PCBA 118 is positioned within sealed enclosure 114 so that it will be at least partially submerged in immersion cooling fluid 116, and cold plate 126 (also not shown in this figure, but see FIGS. 1A-1C) is thermally coupled to the major components on top surface 120U. To allow for easier removal of PCBA 118 and board-end connector 202 from interior chamber 114, cooling device 300 includes a fill port 214 in lid 104 and a drain port 216 in bottom 106.

The primary difference between cooling devices 200 and 300 is in the configuration of the board-end and cable-end connectors. In some circumstances it can be necessary to connect and disconnect PCBA 118, and its components, from various external connections (e.g., power, network, and data connections to components outside sealed compartment 114) without leaking or spilling immersion cooling fluid 116. In some embodiments, water-proof connectors may be unavailable, or plugging/unplugging actions might be frequent, so the connector arrangement of hybrid liquid cooling device 200 is not practical. The connector arrangement in device 300 provides an alternative way of achieving this capability. Device 300 uses a different connector arrangement with vertical connectors facing upward. The connectors' mating faces can be above the liquid line of the immersion cooling fluid, and the plugging and unplugging action will not cause continuous spilling of the coolant.

As in device 200, a board-end connector 302 is mounted on PCB 120. In the illustrated embodiment the board-end connector is positioned on upper surface 120U, but in other embodiments it could be positioned on lower surface 120L. Board-end connector 302 is electrically coupled to PCB 120, and thus to the components mounted on the PCB, through conductive paths 304 that extend through the connector. In one embodiment conductive paths 304 can be wires embedded in the board-end connector, but in other embodiments they can be other types of conductive paths or traces within the board-end connector.

Board-end connector 302 projects upward from upper surface 120U but remains fully within the sealed compartment 114. In the illustrated embodiment, top surface 302U of the board-end connector is above the surface of immersion cooling fluid 116—i.e., top surface 302U is not immersed in the immersion cooling fluid. But because the immersion cooling fluid is dielectric, in other embodiments top surface 302U can be below the level of the immersion cooling fluid surface, so that board-end connector 302 is fully submerged in the immersion cooling fluid.

Cable-end connector 308 and its associated cable 310 extend through lid 104—that is, the cable and cable-end connector extend from where the cable-end connector is coupled to board-end connector 302, through sealed enclosure 114, through internal surface 104i of the lid, and through external surface 104e of the lid. Cable-end connector 308 can include pins or wires 310 that make electrical contact with conductive paths 304 when cable-end connector 308 is mated with board-end connector 302.

In some embodiments—for instance, in embodiments where upper surface 302U of board- and connector 302 and its interface with cable-end connector 308 should be kept as dry as possible—it can be useful to position one or more baffles 314 within sealed enclosure 114 to reduce or prevent sloshing of immersion cooling fluid 116. Sloshing of the immersion cooling fluid can occur, for instance, due to acceleration, deceleration, or turning of a vehicle in which cooling device 300 is located. The illustrated embodiment has three baffles 314 positioned substantially around or near board-end connector 302, but other embodiments can include more or less baffles than shown and they can be positioned differently than shown. Also in the illustrated embodiment, baffles 314 extend downward from lid 104 and sidewall 108, but in other embodiments baffles can be positioned differently than shown. Similar baffle structures can also be added to the system to minimize fluid flow impacts during acceleration and deceleration. But because the immersion cooling fluid is usually denser and more viscous than water, and because the total mass in the computing system is so low, in some implementations fluid sloshing might not be a concern.

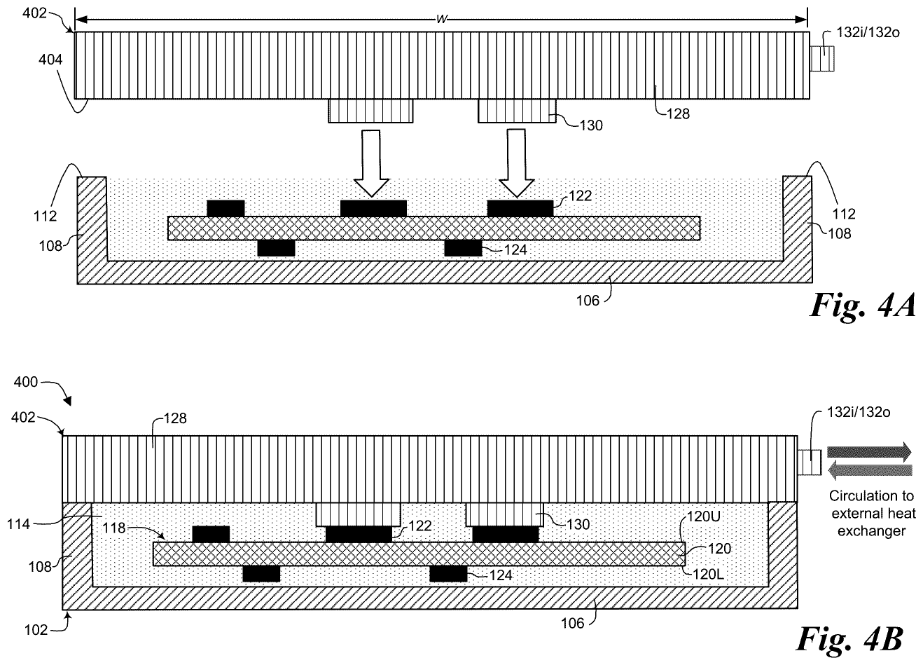

FIGS. 4A-4B together illustrate another embodiment of a hybrid liquid cooling device 400; FIG. 4A is an exploded side view, FIG. 4B an assembled side view. Cooling device 400 is similar to cooling device 100: it includes a housing with a body 102, and body 102 includes a bottom 106 and at least one sidewall 108. PCBA 118 includes PCB 120 and all the major electronic components 122 attached to upper surface 120U and minor electronic components 124 mounted on lower surface 120L, and PCBA 118 is positioned within sealed enclosure 114 so that it is at least partially submerged in immersion cooling fluid 116. These common elements of cooling devices 100 and 400 are subject to the same variations described above for different embodiments of device 100.

The primary difference between cooling devices 100 and 400 is in the configuration and position of the cold plate. In cooling device 100, cold plate 126 is positioned inside sealed enclosure 114, and the sealed enclosure is formed by the body and by a lid that is separate from the cold plate. In cooling device 400, on the other hand, the functions of the lid and cold plate are combined. Put differently, in device 400 cold plate 402, in addition to performing its cooling functions, forms the device's lid and, together with body 102, forms sealed enclosure 114.

Cold plate 402 has a bottom surface 404 designed to engage with the top ends 112 of sidewalls 108. Because cold plate 402 forms the lid of the enclosure instead of fitting entirely within the enclosure like cold plate 126, at least one of its dimensions will be larger than the corresponding dimension in cold plate 126. That is, to allow cold plate 402 to engage with the top ends 112 of the sidewalls instead of being fully within sealed enclosure 114, its width W, depth H (see FIG. 1C), or both, can be made larger than the corresponding dimensions of cold plate 126.

Surface 404 engages with the top ends 112 in a way that creates a sealed enclosure 114 (see FIG. 1B). In one embodiment the plan-view shape and size of cold plater 402 substantially match the shape and size of body 102, but in other embodiments the shape and size of the lid need not match the shape and size of the body. As in device 100, sealed enclosure 114 is adapted to be at least partially filled with an immersion cooling fluid 116. Although not shown in the figure, one or more seals such as gaskets, O-rings, or the like can be positioned between top ends 112 and bottom surface 404 to create a seal that prevents immersion cooling fluid 116 from leaking out of sealed enclosure 114.

Aside from its different size and its different position in the assembly, cold plate 402 is in most respect similar to cold plate 126 and operates similarly. Cold plate 402 includes a main body 128, which includes an internal chamber (not shown) through which a circulating cooling fluid circulates, and in some embodiments can include protrusions 130 whose height h can be tailored to the different heights H of the major components 124 to ensure that when cold plate 402 is installed it will be in thermal contact with all major components 122 (see FIGS. 1A-1B). When present, protrusions 130 can be thermally and fluidly coupled to the internal chamber within main body 128, so that heat can be transferred through the protrusion into the circulating fluid. Protrusions 130 can also be used to create a gap G—i.e., a non-zero distance—between main body 128 and minor components 124 positioned on upper surface 120U. Gap G allows immersion cooling fluid 116 to circulate around minor components 124 on upper surface 120U, improving heat transfer from the electronic components into the immersion cooling fluid. The gap also prevents electrical shorts that could occur if main body 128 comes into physical contact with a minor component 124.

Main body 128 is fluidly coupled to an external heat exchanger 134 and pump P—i.e., a heat exchanger and pump that are outside sealed enclosure 114 (see, e.g., FIG. 1C)—by a fluid interface that includes an inlet 132i and an outlet 1320. In the illustrated embodiment, inlet 132i and outlet 1320 do not extend through a sidewall 108 as in device 100, but instead, because of the position of cold plate 402, are completely outside the sealed enclosure. The connector arrangements of devices 200 and 300 can both be deployed in device 400.

FIG. 5 illustrates an embodiment of a vehicle 500 with a hybrid liquid cooling system such as system 150 (see FIG. 1C). In one embodiment vehicle 500 can be an autonomous driving vehicle (ADV), but in other embodiments it need not be autonomous. Vehicle 500 includes a chassis 502 within which there are several compartments. The illustrated embodiment has three compartments: an engine compartment 504 at or near the front of the chassis, a passenger compartment 506 in the middle of the chassis, and a trunk compartment 508 at or near the rear of chassis 502. Other embodiments of vehicle 500 can, of course, have a different number and arrangement of compartments; for instance, in a rear-engine vehicle engine compartment 504 can be at the rear instead of the front, and in a mid-engine vehicle engine compartment 504 can be at or near the middle of the chassis, for instance surrounded by the passenger compartment.

In the illustrated embodiment a hybrid liquid cooling device 510 is positioned in passenger compartment 506; hybrid liquid cooling device 510 can be implemented with any of hybrid liquid cooling devices 100, 200, 300, or 400 described above. In one embodiment the electronics within hybrid liquid cooling device are computing hardware for level four (L4) and level five (L5) fully autonomous driving (i.e., driverless) platforms. Although not shown in the drawing, in fully autonomous embodiments the L4 or L5 computing hardware can be coupled to a vehicle control system so that the computing hardware can control the speed, direction, or other handling characteristics of vehicle 500.

Hybrid liquid cooling device 510—or, more specifically, the cold plate within the hybrid liquid cooling device—is fluidly coupled to radiator 512, with the inlet of radiator 512 coupled to the outlet of hybrid liquid cooling device 510 (i.e., to the outlet of the cold plate) and the outlet of radiator 512 fluidly coupled to the inlet of hybrid liquid cooling device 510 (i.e., to the inlet of the cold plate). A pump P is coupled in the fluid line between the outlet of the radiator and the inlet of hybrid liquid cooling device 510 to circulate cooling fluid through both radiator 512 and hybrid liquid cooling device 510 when the ADV is operating, substantially as described above for thermal control system 200.

The above description of embodiments is not intended to be exhaustive or to limit the invention to the described forms. Specific embodiments of, and examples for, the invention are described herein for illustrative purposes, but various modifications are possible.

What is claimed is:

1. A cooling apparatus comprising:
a housing having a lid, a bottom, and at least one sidewall, wherein the lid, the bottom, and the at least one sidewall form a sealed enclosure adapted to be at least partially filled with an immersion cooling fluid;
a printed circuit board assembly (PCBA) positioned in the sealed enclosure, the PCBA including one or more major electronic components and one or more minor electronic components; and
a cold plate at least part of which is positioned in the sealed enclosure, wherein the cold plate is thermally coupled to the one or more major components and is at least partially submerged in the immersion cooling fluid.

2. The cooling apparatus of claim 1, further comprising baffles positioned in the sealed enclosure to prevent sloshing of the immersion cooling fluid.

3. The cooling apparatus of claim 1, further comprising a board-end connector coupled to the PCBA.

4. The cooling apparatus of claim 3 wherein the board-end connector extends through the at least one sidewall from an interior side of the sidewall to an exterior side of the sidewall.

5. The cooling apparatus of claim 4, further comprising a seal positioned at or near where the board-end connector exits the exterior side of the sidewall.

6. The cooling apparatus of claim 3, further comprising a cable-end connector connected to the board-end connector and extending through the lid.

7. The cooling apparatus of claim 1, further comprising a fill port for filling the sealed enclosure with the immersion cooling fluid and a drain port for draining the immersion cooling fluid from the sealed enclosure.

8. The cooling apparatus of claim 1, further comprising a forced-convection device positioned in the sealed enclosure to force convection of the immersion cooling fluid.

9. The cooling apparatus of claim 1 wherein the lid is formed by the cold plate.

10. An electronics cooling system comprising:
a housing having a lid, a bottom, and at least one sidewall, wherein the lid, the bottom, and the at least one sidewall form a sealed enclosure adapted to be at least partially filled with an immersion cooling fluid;
a printed circuit board assembly (PCBA) positioned in the sealed enclosure, the PCBA including one or more major electronic components and one or more minor electronic components;
a cold plate at least part of which is positioned in the sealed enclosure, wherein the cold plate is thermally coupled to the one or more major components and is at least partially submerged in the immersion cooling fluid;
a heat exchanger fluidly coupled to an inlet and an outlet of the cold plate, wherein the heat exchanger is positioned outside the sealed enclosure; and
a pump coupled between the cold plate and the heat exchanger to circulate a circulation cooling fluid through the cold plate and the heat exchanger.

11. The system of claim 10 wherein the pump is coupled upstream of the inlet of the cold plate.

12. The system of claim 10, further comprising a board-end connector coupled to the PCBA.

13. The system of claim 12 wherein the board-end connector extends through the at least one sidewall from an interior side of the sidewall to an exterior side of the sidewall.

14. The system of claim 13, further comprising seals positioned at or near where the board-end connector exits the exterior side.

15. The system of claim 12, further comprising a cable-end connector connected to the board-end connector and extending through the lid.

16. The cooling apparatus of claim 10 wherein the lid is formed by the cold plate.

17. An electronics cooling system for a vehicle, the system comprising:
a cooling apparatus positioned in a compartment of the vehicle, the cooling apparatus comprising:
a housing having a lid, a bottom, and at least one sidewall, wherein the lid, the bottom, and the at least one sidewall form a sealed enclosure adapted to be at least partially filled with an immersion cooling fluid,
a printed circuit board assembly (PCBA) positioned in the sealed enclosure, the PCBA including one or more major electronic components and one or more minor electronic components, and
a cold plate at least part of which is positioned in the sealed enclosure, wherein the cold plate is thermally coupled to the one or more major components and is at least partially submerged in the immersion cooling fluid;
a heat exchanger positioned outside the sealed enclosure and fluidly coupled to an inlet and an outlet of the cold plate; and
a pump coupled between the cold plate and the heat exchanger to circulate a circulation cooling fluid through the cold plate and the heat exchanger.

18. The system of claim 10, further comprising a board-end connector coupled to the PCBA.

19. The system of claim 18 wherein the board-end connector extends through the at least one sidewall from an interior side of the sidewall to an exterior side of the sidewall, and further comprising seals positioned at or near where the board-end connector exits the exterior side.

20. The system of claim 18, further comprising a cable-end connector connected to the board-end connector and extending through the lid.
